(19) United States
(12) Patent Application Publication
(10) Pub. No.: US 2010/0320456 A1
(43) Pub. Date: Dec. 23, 2010

(54) Method for Fabricating a Doped and/or Alloyed Semiconductor

(75) Inventors: Alan E. DELAHOY, Rocky Hill, NJ (US); Gaurav SARAF, Santa Clara, CA (US); Sheyu GUO, Wallingford, PA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: EPV Solar, Inc., Robbinsville, NJ (US)

(21) Appl. No.: 12/488,218

(22) Filed: Jun. 19, 2009

(51) Int. Cl. H01L 29/227; H01L 21/36; C23C 14/34; C23C 14/50; H01L 21/40

(52) U.S. Cl. 257/43; 438/478; 204/298.02; 204/298.23; 257/E21.461; 257/E21.47; 257/E29.098

(57) ABSTRACT

The present invention is directed to methods for depositing doped and/or alloyed semiconductor layers, an apparatus suitable for the depositing, and products prepared therefrom.

### BACKGROUND OF THE INVENTION

1. Field of the Invention

The present invention relates to methods of depositing doped and/or alloyed semiconductor layers, an apparatus suitable for depositing doped and/or alloyed semiconductor layers, and products prepared therefrom.

2. Background of the Invention

Transparent Conductive Oxides (TCOs) are present in many consumer electronic devices and are a critical element for the development of high-efficiently photovoltaic devices. Applications for TCO thin films include transparent electrodes for flat panel displays, transparent electrodes for photovoltaic cells, low emissivity windows, window defrosters, transparent thin film transistors, light emitting diodes, semiconductor lasers, and the like. A TCO layer is often an integral part of thin-film solar cells, usually as a sun-facing (top) contact or as a back reflector in silicon-based solar cells. However, the usefulness of TCO thin films in solar cell applications depends strongly on the optical, electrical, and morphological properties of the TCO. Other factors that can affect TCO selection can include cost, ease of manufacture, environmental stability, abrasion resistance, electron work function, and compatibility with a substrate and the other layers of a device. For example, the scarcity, high cost, and non-negligible toxicity of indium, which is required for Indium Tin Oxide (ITO), the most popular TCO, has spurred the search for additional TCOs having the necessary carrier density and resistivity for commercial applications.

Typical requirements for a TCO material include high optical transmission, low sheet resistance, and low resistivity (which is typically provided by doping a material with an electrically active dopant that can contribute free carriers). However, at high dopant concentrations many materials suffer from reduced optical transmission due to increased light absorption (free carrier absorption) and impurity scattering. Thus, in many cases optical transmission is sacrificed for optimizing electrical properties, and vice versa. Doped zinc oxides (e.g., aluminum- and gallium-doped zinc oxide) are among the current generation of TCOs that have emerged as promising replacements for ITO. While the constituent elements of ZnO are inexpensive, the film preparation process can suffer from low deposition rate, poor process reproducibility, poor uniformity and general unsuitability for large area coating. Any combination of these drawbacks can lead to a high cost of the final ZnO thin film product.

Several deposition techniques have been utilized in an attempt to deposit doped

TCOs inexpensively and over large surface areas. The deposition methods include chemical vapor deposition (e.g., CVD, MOCVD, and the like), molecular beam epitaxy (MBE), pulsed laser deposition (PLD), and sputtering (e.g., RF sputtering and DC sputtering). Chemical vapor deposition is the preferred technique for providing highly crystalline thin films in which control over composition (e.g., for doping and/or alloying) is critical. However, physical deposition techniques such as sputtering (e.g. magnetron sputtering using DC, mid-frequency, or RF power, and including both metallic and reactive sputtering) are preferred for many applications due to their lower cost, higher deposition rates, and ability to uniformly deposit over large surface areas. The major problem with physical deposition techniques such as sputtering is the ability to variably control a dopant composition (e.g., for doping and/or alloying). Specifically, doping and/or alloying of materials deposited by sputtering requires complex and cumbersome target preparation that typically requires several elements or compounds to be mixed and formed into a target having a fixed composition. Moreover, variability in dopant concentration requires the use of multiple chambers and/or multiple sputtering targets for each dopant concentration that is desired. For example, conventional sputtering of an intrinsic ZnO layer followed by a doped conducting ZnO layer (e.g., for use in a CIGS solar cell) requires the use of multiple targets (i.e., separate targets for each layer). Thus, sputtering processes are not sufficiently flexible to be cost effective for applications that require the deposition of multiple layers having variable compositions or that require adjustments to be made to the composition of a layer to satisfy properties demanded of the layer.

### BRIEF SUMMARY OF THE INVENTION

What is needed is a deposition technique that can easily optimize the dopant concentration in a TCO, and while providing uniform dopant concentration over large surface area substrates, while maintaining the desired structural, optical and electrical properties. What is needed is a method that can readily provide doped and/or alloyed semiconductor layers using a single target material. The present invention provides a physical deposition process (i.e., sputtering) that is more flexible, more cost effective and less complicated than current deposition techniques. Specifically, the present invention permits in-situ composition control for doped and/or alloyed thin films, and permits facile control over varying the composition of doped and/or alloyed thin films that are used in multilayer devices. The present invention substantially reduces or eliminates the need for using multiple sputtering targets, or for designing and implementing sputtering targets having a doped composition, in order to deposit doped and/or alloyed films.

The present invention is directed to a method for depositing a semiconductor layer on a substrate, the method comprising: sputtering a material from a target onto a substrate to provide a semiconductor layer, while simultaneously doping and/or alloying the semiconductor layer with a metalorganic precursor.

In some embodiments, the sputtering the material and the doping and/or alloying occur within a single deposition chamber.

In some embodiments, the doping and/or alloying comprises providing to the substrate a decomposition product of the metalorganic precursor. In some embodiments, the decomposition of the metalorganic precursor occurs via plasma activation, thermal activation, or a combination thereof.

In some embodiments, the sputtering comprises a target that includes a metal selected from: zinc, aluminum, titanium, tin, indium, hafnium, an oxide thereof, and combinations thereof.

In some embodiments, the sputtering includes a process selected from: magnetron sputtering and non-magnetron sputtering. In some embodiments, the sputtering comprises an excitation provided by radiofrequency current, mid-frequency current, direct current, or pulsed direct current.

In some embodiments, the method further comprises providing a reactive gas during the sputtering and the doping and/or alloying.

In some embodiments, the sputtering a material from a target comprises:
(a) providing a surface, wherein one or more portions of the surface include a target material;
(b) flowing a gas into a region proximate to the surface;
(c) generating a plasma in the region proximate to the surface;
(d) sputtering the target material from the surface; and
(e) depositing the sputtered target material on the substrate.

In some embodiments, the flowing a gas comprises an inert gas.

In some embodiments, the method further comprises reacting at least a portion of the sputtered target material with a reactive species. In some embodiments, the reacting comprises providing a reactive oxidizing species to the substrate.

In some embodiments, the generating a plasma comprises providing a power density of about 3 W/cm² to about 25 W/cm².

In some embodiments, the transporting further comprises providing a distance between the surface and the substrate of about 3 cm to about 8 cm.

In some embodiments, the doping and/or alloying comprises:
(a) flowing a metalorganic precursor into the deposition chamber;
(b) decomposing the metalorganic precursor to form a doping and/or alloying species; and
(c) providing the doping and/or alloying species to the substrate.

In some embodiments, the flowing comprises providing the metalorganic precursor in an after-glow region of a plasma.

In some embodiments, the flowing includes a metalorganic precursor that contains a metal selected from: a group IIA element, a transition metal, a group III element, a group VI element, and combinations thereof.

In some embodiments, the flowing includes a metalorganic precursor containing a metal selected from: gallium, aluminum, indium, magnesium, cadmium, iron, and combinations thereof.

In some embodiments, the flowing includes a metalorganic precursor selected from: trimethylgallium, triethylgallium, tripropylgallium, triethylaluminum, tripropylaluminum, tributylaluminum, diethylaluminum hydride, dipropylaluminum hydride, dibutylaluminum hydride, trimethylindium, bismethylcyclopentadienyl magnesium, dimethylcadmium, bicyclopentadienyl iron, and combinations thereof.

In some embodiments, the flowing includes a metalorganic precursor containing gallium, and the sputtering comprises one or more targets that include zinc, aluminum, or a combination thereof.

In some embodiments, the method further comprises maintaining the substrate at a temperature of about 25° C. to about 500° C.

In some embodiments, the method further comprises maintaining a pressure during the sputtering and the doping and/or alloying of about 100 mTorr to about 1 Torr.

In some embodiments, the sputtering the material and the doping and/or alloying provides a dynamic deposition rate for the semiconductor layer of about 5 nm·m/min to about 100 nm·m/min.

The present invention is also directed to a product prepared by above methods.

In some embodiments, the product is a doped and/or alloyed zinc oxide layer having a single crystalline orientation. In some embodiments, the product is a doped and/or alloyed zinc oxide layer having a polycrystalline orientation.

In some embodiments, the product is a doped zinc oxide layer comprising aluminum, gallium, or a combination thereof in a molar concentration of about 0.1% to about 30%. In some embodiments, a doped zinc oxide layer prepared by the method of the present invention has a specific crystal orientation and comprises gallium in a molar concentration of about 0.1% to about 15%. In some embodiments, the product is a gallium-doped zinc oxide layer having a refractive index of less than about 1.80 (as measured at a wavelength of about 600 nm). In some embodiments, a doped zinc oxide layer prepared by the method of the present invention has a specific crystal orientation and comprises aluminum in a molar concentration of about 0.1% to about 15%.

In some embodiments, the product is a zinc oxide layer alloyed with magnesium, cadmium, or a combination thereof.

The present invention is also directed to an apparatus comprising a deposition chamber that includes:

(a) a surface that includes a target material;
(b) a cathode assembly to support the surface that includes a target material;
(c) a means for sputtering the target material from the surface;
(d) a gas source;
(e) a metalorganic precursor source; and
(f) a means for positioning a substrate a distance from the surface.

In some embodiments, the cathode assembly includes a linear hollow cathode.

In some embodiments, the gas source comprises an inert gas source and a reactive gas source.

In some embodiments, the means for positioning a substrate is suitable for positioning a substrate about 3 cm to about 8 cm from the surface that includes a target material or from an exit aperture of a hollow cathode.

In some embodiments, the means for positioning a substrate is suitable for positioning a substrate about 1 cm to about 4 cm from metalorganic precursor source.

In some embodiments, the cathode assembly is suitable for generating a plasma having a planar power density of about 3 W/cm² to about 25 W/cm².

In some embodiments, the apparatus further comprises an oxidant source.

In some embodiments, the apparatus further comprises a means for controlling a temperature of a substrate at about 25° C. to about 500° C.

Further embodiments, features, and advantages of the present inventions, as well as the composition, structure and operation of the various embodiments of the present invention, are described in detail below with reference to the accompanying drawings.

### BRIEF DESCRIPTION OF THE FIGURES

The accompanying drawings, which are incorporated herein and form a part of the specification, illustrate one or more embodiments of the present invention and, together with the description, further serve to explain the principles of the invention and to enable a person skilled in the pertinent art to make and use the invention.

FIGS. 1A-1B provide schematic representations of cross-sectional views of a portion of deposition apparatus of the present invention.

FIG. 2 provides a schematic representation of a cross-sectional view of a portion of an apparatus suitable for providing a metalorganic precursor to a deposition chamber.

FIG. 3 provides a schematic representation of a top view of a portion of a deposition apparatus of the present invention.

FIGS. 4A-4B, 5A-5B and 6A-6B provide dynamic secondary ion mass spectrometric spectra for an undoped zinc oxide and gallium-doped zinc oxide layers of the present invention.

FIGS. 7A-7B provide optical transmission and absorption spectra, respectively, for undoped zinc oxide and gallium-doped zinc oxide layers of the present invention.

FIGS. 8 and 9 provide x-ray scattering spectra for an undoped zinc oxide and gallium-doped zinc oxide layers, respectively, of the present invention

One or more embodiments of the present invention will now be described with reference to the accompanying drawings. In the drawings, like reference numbers can indicate identical or functionally similar elements. Additionally, the left-most digit(s) of a reference number can identify the drawing in which the reference number first appears.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

As used herein, “a,” “an” and “the” include plural references unless the context clearly indicates otherwise.

The terms “comprising,” “having,” “including,” and “containing” are to be construed as open-ended terms (i.e., meaning “including, but not limited to”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. No language in the specification should be construed as indicating any non-claimed element as essential to the practice of the invention.

All references to spatial descriptions (e.g., “above,” “below,” “up,” “down,” “top,” “bottom,” etc.) made herein are for purposes of description and illustration only, and should be interpreted as non-limiting upon the compositions, formulations, and methods of making and using the same, which can be spatially arranged in any orientation or manner.

The invention includes combinations and sub-combinations of the various aspects and embodiments disclosed herein. Further, when a particular feature, structure, or characteristic is described in connection with an embodiment, it is understood that it is within the knowledge of one skilled in the art to effect such feature, structure, or characteristic in connection with other embodiments whether or not explicitly described. These and other aspects of this invention will be apparent upon reference to the following detailed description, examples, claims and attached figures.

The present invention is directed to a method for depositing a semiconductor layer on a substrate, the method comprising: sputtering a material from a target onto a substrate to provide a semiconductor layer, while simultaneously doping and/or alloying the semiconductor layer with a metalorganic precursor.

In some embodiments, the sputtering the material and the doping and/or alloying occur within a single deposition chamber.

In some embodiments, the doping and/or alloying comprises providing to the substrate a decomposition product of the metalorganic precursor.

The method of the present invention comprises decomposing a metalorganic precursor. As used herein, “decomposition” refers to a reaction in which one or more chemical bonds are broken. Decomposition typically involves formation of a metal or a radical from a metalorganic precursor. Decomposition can also include partial decomposition reactions, in which one or more metal-organic bonds are retained in the doping and/or alloying species. A decomposition product is suitable for doping and/or alloying a semiconductor layer.

Decomposition can occur via any mechanism suitable for breaking a metal-organic chemical bond. In some embodiments, the decomposition of the metalorganic precursor occurs via plasma activation, thermal activation, or a combination thereof. In some embodiments, decomposition can utilize a catalytic species suitable for promoting bond breaking.

The present invention utilizes a sputtering target as a source of a semiconductor material. Targets suitable for depositing semiconductor materials via sputtering processes are well known in the electronic device and semiconductor material arts. Materials suitable for use in sputtering targets of the present invention include, but are not limited to, zinc, aluminum, titanium, tin, indium, hafnium, oxides thereof, and combinations thereof.

In some embodiments, the target material comprises zinc or a zinc oxide. Zinc oxide (ZnO) is an important wide-bandgap semiconductor material that has found broad application in electronic, optoelectronic, sensors and solar cell applications, most often in thin film form. Doping and alloying of ZnO with various elements makes ZnO a multifunctional material that can be transparent, conducting (e.g., when doped with group III elements such as B, Al, Ga, In, and the like), semiconducting, insulating (e.g., when doped with Ni, Li, and the like), piezoelectric (e.g., when doped with Ni, Li, Cu, and the like), or ferromagnetic (e.g., when doped with transition metals such as Co, Ni, Fe, Mn, and the like). Bandgap engineering is also possible by alloying ZnO with group IIA elements such as Be, Mg, Ca, Sr, and the like.

As used herein, “sputtering” refers to a process in which material is removed from a target by ion bombardment and subsequently deposited on a substrate. Sputtering processes are well known in the semiconductor and electronic device arts, and the present invention includes both magnetron and non-magnetron sputtering processes. Sputtering processes suitable for use with the present invention include, but are not limited to, physical sputtering, electronic sputtering, potential sputtering, heat spike sputtering, combinations thereof, and other sputtering processes known to persons of ordinary skill in the art of semiconductor manufacturing.

In some embodiments, the sputtering comprises plasma sputtering. In some embodiments, the sputtering comprises an excitation provided by radiofrequency current, mid-frequency current, direct current, or pulsed direct current.

In some embodiments, the sputtering a material from a target comprises:
(a) providing a surface, wherein one or more portions of the surface include a target material;
(b) flowing a gas into a region proximate to the surface;
(c) generating a plasma in the region proximate to the surface;
(d) sputtering the target material from the surface; and
(e) depositing the sputtered target material on the substrate.

In some embodiments, the flowing a gas comprises an inert gas. Inert gases include, but are not limited to, helium, neon, krypton, argon, xenon, and combinations thereof. In some embodiments, an inert gas suitable for generating a plasma suitable for sputtering a target material comprises argon.

In some embodiments, the generating a plasma comprises providing a power density of about 3 W/cm² to about 25 W/cm², about 3 W/cm² to about 20 W/cm², about 3 W/cm² to about 15 W/cm², about 3 W/cm² to about 12 W/cm², about 3 W/cm² to about 10 W/cm², about 3 W/cm² to about 8 W/cm², about 5 W/cm² to about 25 W/cm², about 5 W/cm² to about 20 W/cm², about 5 W/cm² to about 15 W/cm², about 5 W/cm² to about 10 W/cm², about 10 W/cm² to about 25 W/cm², about 10 W/cm² to about 20 W/cm², about 15 W/cm² to about 25 W/cm², about 20 W/cm² to about 25 W/cm², about 3 W/cm², about 5 W/cm², about 10 W/cm², about 15 W/cm², about 20 W/cm², or about 25 W/cm².

The present invention can optionally include a reactive sputtering process, in which a target material is sputtered and then undergoes chemical reaction after sputtering. Thus, in some embodiments, the method further comprises reacting at least a portion of the sputtered target material with a reactive species. Such a reactive sputtering method provides a semiconductor layer having a chemical composition different from the chemical composition of a target material.

As used herein, a “reactive gas” refers to a gaseous species capable of forming a chemical bond with a sputtered moiety. A reactive gas can react with a sputtered material in the plasma phase, in the gas phase (via an interaction between gaseous species), or in the solid phase (via an interaction between a surface and a gaseous species). Reactive species include, but are not limited to oxygen, boron, nitrogen, fluorine, and the like, and combinations thereof.

Not being bound by any particular theory, a reactive species can include any moiety provided by a reactive gas precursor. For example, a reactive species such as atomic oxygen can be provided by a reactive gas such as, but not limited to, oxygen, ozone, water, and the like. A reactive gas can decompose, or otherwise react, in the gas phase, the plasma phase, or on a surface, to provide a reactive species that is incorporated into a semiconductor layer. In an embodiment, zinc is sputtered from a metal target and oxygen is introduced to provide a zinc oxide layer in which a reaction between zinc and a reactive oxygen species occurs primarily via a surface reaction (i.e., sputtered zinc is deposited on a substrate and then reacts with a reactive oxygen species to form a zinc oxide). Thus, in some embodiments, the reacting comprises providing a reactive oxidizing species to the substrate.

In some embodiments, the transporting further comprises providing a distance between the surface and the substrate of about 3 cm to about 8 cm.

In some embodiments, the doping and/or alloying comprises:
(a) flowing a metalorganic precursor into the deposition chamber;
(b) decomposing the metalorganic precursor to form a doping and/or alloying species; and
(c) providing the doping and/or alloying species to the substrate.

In some embodiments, the flowing comprises providing the metalorganic precursor in an after-glow region of a plasma.

In some embodiments, a metalorganic precursor for use with the present invention comprises a metal selected from: a group IIA element, a transition metal, a group III element, a group VI element, and combinations thereof.

In some embodiments, a metalorganic precursor for use with the present invention comprises a metal selected from: gallium, aluminum, indium, magnesium, cadmium, iron, and combinations thereof.

In some embodiments, a metalorganic precursor for use with the present invention is selected from: trimethylgallium, triethylgallium, tripropylgallium, triethylaluminum, tripropylaluminum, tributylaluminum, diethylaluminum hydride, dipropylaluminum hydride, dibutylaluminum hydride, trimethylindium, bismethylcyclopentadienyl magnesium, dimethylcadmium, bicyclopentadienyl iron, and combinations thereof.

In some embodiments, the method further comprises maintaining the substrate at a temperature of about 25° C. to about 500° C., about 25° C. to about 400° C., about 25° C. to about 300° C., about 25° C. to about 250° C., about 25° C. to about 200° C., about 50° C. to about 500° C., about 50° C. to about 400° C., about 50° C. to about 300° C., about 100° C. to about 500° C., about 100° C. to about 450° C., about 100° C. to about 400° C., about 100° C. to about 350° C., about 100° C. to about 250° C., about 150° C. to about 500° C., about 150° C. to about 450° C., about 150° C. to about 400° C., about 150° C. to about 350° C., about 150° C. to about 300° C., about 200° C. to about 500° C., about 200° C. to about 450° C., about 200° C. to about 400° C., about 200° C. to about 350° C., about 200° C. to about 300° C., about 250° C. to about 500° C., about 250° C. to about 450° C., about 250° C. to about 400° C., about 250° C. to about 350° C., about 300° C. to about 500° C., about 300° C. to about 450° C., about 300° C. to about 400° C., about 350° C. to about 500° C., about 350° C. to about 450° C., about 400° C. to about 500° C., about 25° C., about 50° C., about 100° C., about 150° C., about 200° C., about 250° C., about 300° C., about 350° C., about 400° C., about 450° C., or about 500° C.

Generally, the deposition methods of the present invention are conducted at sub-atmospheric pressure. Depending on the sputtering method that is utilized, a pressure is maintained accordingly. Thus, in some embodiments, and particularly in the case of hollow cathode sputtering, a method further comprises maintaining a pressure during the sputtering and the doping and/or alloying of about 100 mTorr to about 1 Torr, about 100 mTorr to about 750 mTorr, about 100 mTorr to about 500 mTorr, about 100 mTorr to about 250 mTorr, about 250 mTorr to about 1 Torr, about 250 mTorr to about 750 mTorr, about 250 mTorr to about 500 mTorr, about 500 mTorr to about 1 Torr, about 500 mTorr to about 750 mTorr, about 100 mTorr, about 200 mTorr, about 250 mTorr, about 300 mTorr, about 400 mTorr, about 500 mTorr, about 600 mTorr, about 750 mTorr, about 800 mTorr, about 900 mTorr, or about 1 Torr. In some embodiments, a method of the present invention comprise magnetron sputtering at a pressure of about 1 mTorr to about 15 mTorr.

In some embodiments, a method of the present invention provides a deposition rate for a doped and/or alloyed semiconductor layer of about 5 nm/min to about 500 nm/min, about 5 nm/min to about 250 nm/min, about 5 nm/min to about 100 nm/min, about 5 nm/min to about 50 nm/min, about 5 nm/min to about 25 nm/min, about 5 nm/min to about 10 nm/min, about 50 nm/min to about 500 nm/min, about 50 nm/min to about 250 nm/min, about 50 nm/min to about 100 nm/min, about 100 nm/min to about 500 nm/min, about 100 nm/min to about 250 nm/min, about 250 nm/min to about 500 nm/min, about 5 nm/min, about 10 nm/min, about 25 nm/min, about 50 nm/min, about 100 nm/min, about 250 nm/min, or about 500 nm/min.

As used herein, a “dynamic deposition rate” refers to a deposition rate of a semiconductor layer on a substrate in which the substrate and/or the sputtering target are moved relative to one another during the depositing. In some embodiments, the sputtering the material and the doping and/or alloying provides a dynamic deposition rate for the semiconductor layer of about 5 nm·m/min to about 100 nm·m/min, about 5 nm·m/min to about 90 nm·m/min, about 5 nm·m/min to about 75 nm·m/min, about 5 nm·m/min to about 50 nm·m/min, about 5 nm·m/min to about 25 nm·m/min, about 10 nm·m/min to about 100 nm·m/min, about 10 nm·m/min to about 75 nm·m/min, about 10 nm·m/min to about 50 nm·m/min, about 10 nm·m/min to about 25 nm·m/min, about 10 nm·m/min to about 20 nm·m/min, about 20 nm·m/min to about 100 nm·m/min, about 20 nm·m/min to about 75 nm·m/min, about 20 nm·m/min to about 50 nm·m/min, about 25 nm·m/min to about 100 nm·m/min, about 30 nm·m/min to about 100 nm·m/min, about 5 nm·m/min, about 10 nm·m/min, about 20 nm·m/min, about 25 nm·m/min, about 50 nm·m/min, about 75 nm·m/min, about 90 nm·m/min, or about 100 nm·m/min.

The present invention is also directed to a product prepared by a method of the present invention.

In some embodiments, the product is a doped and/or alloyed zinc oxide layer having a single crystalline orientation. In some embodiments, the product is a doped and/or alloyed zinc oxide layer having a polycrystalline orientation.

In some embodiments, a product of the present invention is a doped zinc oxide layer comprising aluminum, gallium, or a combination thereof in a molar concentration of about 0.1% to about 30%, about 0.1% to about 25%, about 0.1% to about 20%, about 0.1% to about 15%, about 0.1% to about 12%, about 0.1% to about 10%, about 0.1% to about 7.5%, about 0.1% to about 5%, about 0.1% to about 3.5%, about 0.1% to about 2.5%, about 0.1% to about 2%, about 0.1% to about 1%, about 0.1% to about 0.5%, about 0.5% to about 30%, about 0.5% to about 25%, about 0.5% to about 20%, about 0.5% to about 15%, about 0.5% to about 10%, about 0.5% to about 7.5%, about 0.5% to about 5%, about 0.5% to about 3.5%, about 0.5% to about 2.5%, about 1% to about 30%, about 1% to about 25%, about 1% to about 20%, about 1% to about 15%, about 1% to about 10%, about 1% to about 7.5%, about 1% to about 5%, about 1% to about 3.5%, about 1% to about 2.5%, about 2.5% to about 30%, about 2.5% to about 25%, about 2.5% to about 20%, about 2.5% to about 15%, about 2.5% to about 10%, about 2.5% to about 7.5%, about 5% to about 30%, about 5% to about 25%, about 5% to about 20%, about 5% to about 15%, about 5% to about 12%, about 5% to about 10%, about 10% to about 30%, about 10% to about 25%, about 10% to about 20%, about 0.1%, about 0.5%, about 1%, about 2%, about 2.5%, about 3%, about 3.5%, about 5%, about 7.5%, about 10%, about 12%, about 15%, about 20% about 25%, or about 30%.

In some embodiments, a doped zinc oxide layer prepared by the method of the present invention has a specific crystal orientation and comprises gallium in a molar concentration of about 0.1% to about 15%, about 0.1% to about 12%, about 0.1% to about 10%, about 0.1% to about 7.5%, about 0.1% to about 5%, about 0.1% to about 2.5%, about 0.1% to about 2%, about 0.1% to about 1%, about 0.1% to about 0.5%, about 0.5% to about 15%, about 0.5% to about 10%, about 0.5% to about 7.5%, about 0.5% to about 5%, about 0.5% to about 2.5%, about 1% to about 15%, about 1% to about 10%, about 1% to about 7.5%, about 1% to about 5%, about 2.5% to about 15%, about 2.5% to about 10%, about 2.5% to about 7.5%, about 5% to about 15%, about 5% to about 12%, about 5% to about 10%, about 0.1%, about 0.5%, about 1%, about 2%, about 2.5%, about 3%, about 3.5%, about 5%, about 7.5%, about 10%, about 12%, or about 15%.

In some embodiments, a product of the method of the present invention is a gallium-doped zinc oxide layer having a refractive index of less than about 1.80, about 1.795 or less, about 1.79 or less, about 1.785 or less, about 1.78 or less, about 1.775 or less, about 1.77 or less, about 1.765 or less, or about 1.76 or less, as measured at a wavelength of about 600 nm.

In some embodiments, a doped zinc oxide layer prepared by the method of the present invention has a specific crystal orientation and comprises aluminum in a molar concentration of about 0.1% to about 15%, about 0.1% to about 12%, about 0.1% to about 10%, about 0.1% to about 7.5%, about 0.1% to about 5%, about 0.1% to about 2.5%, about 0.1% to about 2%, about 0.1% to about 1%, about 0.1% to about 0.5%, about 0.5% to about 15%, about 0.5% to about 10%, about 0.5% to about 7.5%, about 0.5% to about 5%, about 0.5% to about 2.5%, about 1% to about 15%, about 1% to about 10%, about 1% to about 7.5%, about 1% to about 5%, about 2.5% to about 15%, about 2.5% to about 10%, about 2.5% to about 7.5%, about 5% to about 15%, about 5% to about 12%, about 5% to about 10%, about 0.1%, about 0.5%, about 1%, about 2.5%, about 5%, about 7.5%, about 10%, about 12%, or about 15%.

In some embodiments, the product is a zinc oxide layer alloyed with magnesium, cadmium, or a combination thereof.

Doped TCO layers prepared by a method of the present invention can be prepared as specular (smooth) films or as textured films. Textured TCO layers are desirable as superstrates for thin film amorphous silicon (a-Si:H), nanocrystalline silicon (nc-Si:H), and hybrid a-Si:H/nc-Si:H solar cells and photovoltaic modules. In particular, a textured TCO layer promotes light trapping, which can increase the percentage of light that is absorbed by a solar cell. In some embodiments, the present invention is directed to a textured gallium-doped zinc oxide layer is deposited by reactive-environment hollow cathode sputtering, e.g., as described in U.S. Pat. No. 7,235,160, which is incorporated herein by reference in its entirety.

In some embodiments, a doped TCO layer prepared by a method of the present invention has a root mean square (rms) surface roughness of about 5 nm to about 100 nm, about 10 nm to about 90 nm, about 12.5 nm to about 80 nm, about 15 nm to about 75 nm, about 20 nm to about 70 nm, about 25 nm to about 60 nm, about 5 nm, about 10 nm, about 15 nm, about 20 nm, about 25 nm, about 30 nm, about 50 nm, about 75 nm, or about 100 nm.

In some embodiments, the present invention is directed to an aluminum-doped ZnO layer having a resistivity of about 1×10⁻³ Ω·cm or less, about 9×10⁻⁴ Ω·cm or less, about 8×10⁻⁴ Ω·cm or less, about 7×10⁻⁴ Ω·cm or less, about 6×10⁻⁴ Ω·cm or less, about 5×10⁻⁴ Ω·cm or less, about 4×10⁻⁴ Ω·cm or less, about 3×10⁻⁴ Ω·cm or less, or about 2×10⁻⁴ Ω·cm or less. In some the present invention is directed to a gallium-doped ZnO layer having a resistivity of about 2×10⁻³ Ω·cm or less, about 1.5×10⁻³ Ω·cm or less, about 1×10⁻³ Ω·cm or less, about 9×10⁻⁴ Ω·cm or less, about 8×10⁻⁴ Ω·cm or less, about 7×10⁻⁴ Ω·cm or less, about 6×10⁻⁴ Ω·cm or less, about 5×10⁻⁴ Ω·cm or less, or about 4×10⁻⁴ Ω·cm or less.

In particular for gallium-doped zinc oxide (GZO) layers, the level of gallium doping strongly influences the IR transmission and conductivity of the TCO. Both IR transmission and conductivity must be precisely controlled and balanced for solar cell applications in which nc-Si:H is utilized. The deposition methods of the present invention enable precise doping control such that GZO layers prepared by the methods of the present invention are suitable for use in a-Si:H, nc-Si:H, and/or a-Si:H/nc-Si:H solar cells. Thus, in some embodiments a textured GZO layer of the present invention is used as a superstrate (thereby providing a front contact or portion of a front contact) for a thin-film solar cell in order to improve light trapping. And in some embodiments, a GZO layer of the present invention is used as a back contact (or as a portion of a back contact) for a thin-film solar cell in order to improve light reflection and light trapping. The GZO layers prepared by the methods of the present invention also have an electrical work function suitable for forming an electrical contact with a semiconductor, e.g., a p-doped Si—H layer, and the like.

In some embodiments, a TCO of the present invention is used as a front contact for a thin film CIGS solar cell. The deposition method of the present invention is particularly suited for depositing TCO front contact layers onto CIGS films due to the fact that high energy particles do not reach the substrate surface during deposition. Consequently, a TCO layer can be deposited onto an underlying CIGS solar cell without damaging the underlying layers of the cell. The use of a textured TCO layer of the present invention with a CIGS solar cell can also reduce reflection of incident light compared to smooth TCO layers deposited using other methods.

In some embodiments, a method of the present invention is suitable for depositing a doped zinc oxide layer that is environmentally stable. For example, a dopant and/or alloy concentration in a zinc oxide layer of the present invention can be adjusted to optimize the temperature stability of a layer, the moisture stability of a layer, and the like, while retaining a low resistivity. Specifically, doped zinc oxide layers comprising aluminum in a molar concentration of about 10% or higher can be prepared by a method of the present invention, wherein the resulting aluminum-doped ZnO layer is stable in a humid and/or moist environment. In addition, moisture-stable gallium-doped ZnO layers comprising about 5% or less of gallium can be prepared by a method of the present invention.

In some embodiments, a method of the present invention is suitable for preparing a co-doped aluminum-gallium-doped ZnO (“AGZO”) layer having optimized electrical properties and superior stability. A co-doped AGZO layer can prepared using a mixture of a gallium metalorganic precursor and an aluminum metalorganic precursor. In this embodiment, the gallium and aluminum dopant concentration can be fixed, for example, by using a single, mixed metalorganic precursor source, or varied, for example, by using two or more independently controlled metalorganic precursor sources. Thus, in some embodiments the co-dopant concentrations (e.g., aluminum and gallium) can be varied throughout the thickness of a layer.

A co-doped AGZO layer can also prepared by a method in which an aluminum dopant is introduced to the co-doped ZnO layer by a physical co-deposition process (e.g., sputtering), and a gallium copant is introduced to the co-doped ZnO layer using a gallium metalorganic precursor. In such embodiments, a concentration of the aluminum dopant can be fixed by the system geometry (e.g., a sputtering rate, distance separating a target from the substrate, etc.) and target composition, whereas a concentration of the gallium dopant can be varied.

Thus, in some embodiments the flowing includes a metalorganic precursor containing gallium, and the sputtering comprises one or more targets that include zinc, aluminum, or a combination thereof, wherein the targets comprising zinc, aluminum or a combination thereof can be present as separate targets that each include substantially pure zinc or aluminum, or as one or more targets comprising an mixture or alloy of zinc and aluminum.

In addition to solar cells, the doped and/or alloyed layers of the present invention can be conveniently and flexibly deposited for use in any application requiring the presence of a doped, alloyed and/or bandgap-engineered layer or multilayer is required. Exemplary applications in which the doped and/or alloyed layer of the present invention can be utilized include, but are not limited to, bandpass filters, light dispersion gratings, reflective diffraction gratings, transmissive diffraction gratings, distributed Bragg reflectors, and the like. In some embodiments, a doped and/or alloyed semiconductor layer of the present invention is used to improve light trapping in a solar cell.

### Apparatus

The present invention is also directed to an apparatus comprising a deposition chamber that includes:

(a) a surface that includes a target material;
(b) a cathode assembly for supporting the surface that includes a target material;
(c) a means for sputtering the target material from the surface;
(d) a gas source;
(e) a metalorganic precursor source; and
(f) a means for positioning a substrate a distance from the surface.

Target materials suitable for use with the present invention include those described herein, supra.

An apparatus of the present invention includes a means for sputtering the target material from the surface. Means for sputtering include an electrode (i.e., a cathode assembly) and power supply suitable for generating a plasma proximate to the surface, an ion-beam, an electron beam, a heat-spike sputtering apparatus, and the like, and combinations thereof. In some embodiments, a means for sputtering is a magnetron sputtering electrode configuration or a non-magnetron sputtering electrode configuration.

In some embodiments, a means for sputtering the target material from the surface is an hollow cathode assembly and a power supply suitable for generating a plasma proximate to the surface. For example, in some embodiments a target material is present as at least a portion of a cathode surface, and the walls of a deposition chamber and/or the substrate are an anode. A power supply suitable for use with the apparatus of the present invention includes a DC power supply, a pulsed DC power supply, a mid-frequency power supply, or an RF power supply.

In some embodiments, a means for sputtering the target material from the surface is a hollow cathode sputtering apparatus, as described in, e.g., U.S. Pat. Nos. 7,235,160, 6,458,253, 6,337,001, 6,156,172, 6,150,030, 5,889,295, 5,810,982, each of which is incorporated herein by reference in its entirety.

An apparatus of the present invention includes a gas source. A gas source can provide a gas suitable for maintaining a plasma proximate to the cathode assembly and the surface that includes the target material. A gas source can provide a turbulent gas flow (i.e., a gas flow characterized by a Reynolds number greater than 2,000) and/or laminar gas flow proximate to the surface that includes a target material.

In some embodiments, a gas source comprises an inert gas source and a reactive gas source. Inert gases and reactive gases suitable for use with an apparatus of the present invention are provided herein, supra. In some embodiments, a gas source provides an inert gas proximate to the surface that includes a target material and/or the electrode, and provides a reactive gas source to a region between the surface and a substrate. For example, a reactive gas can be provided in an afterglow region of a plasma. In some embodiments, a reactive gas is provided to the substrate. In some embodiments, an apparatus provides a reactive species to a region of a deposition chamber suitable for generation of a reactive species from the reactive gas (e.g., via dissociation and/or reaction of a reactive gas). For example, an apparatus of the present invention can provide an oxidant to a deposition chamber such that atomic oxygen is generated from the oxidant (e.g., via plasma phase reaction, via surface-catalyzed reaction, via gas phase reaction, and/or via thermal reaction).

In some embodiments, the means for positioning a substrate is suitable for positioning a substrate about 3 cm to about 8 cm, about 3 cm to about 7 cm, about 3 cm to about 6 cm, about 3 cm to about 5 cm, about 3 cm to about 4.5 cm, about 3 cm to about 4 cm, about 3 cm to about 3.5 cm, about 4 cm to about 8 cm, about 4 cm to about 6 cm, about 5 cm to about 8 cm, about 5 cm to about 7 cm, about 6 cm to about 8 cm, about 3 cm, about 3.5 cm, about 4 cm, about 4.5 cm, about 5 cm, about 7.5 cm, or about 8 cm from the surface that includes a target material or from an exit aperture of a hollow cathode.

An apparatus of the present invention includes a metalorganic precursor source. A metalorganic precursor source can include, but is not limited to, a showerhead, a ring having distribution points thereon (e.g., a circle, ellipse, oval, semi-circle, and the like), a series of ports, injectors, holes, and the like (having e.g., a rectilinear distribution such as a square, rectangular, or other shape), one or more slits, and the like, and combinations thereof. In some embodiments, a metalorganic precursor source is a gas distribution system having a configuration similar in shape to a rectilinear hollow cathode. In some embodiments, the metal organic precursor source is a linear tube with gas distribution holes therein suitable for providing the metalorganic precursor into a reaction chamber having a hollow cathode configuration. The metalorganic precursor can be distributed into a reactor through the hollow cathode or adjacent to the hollow cathode.

The metalorganic precursor source can introduce a gaseous metalorganic into an apparatus in a turbulent manner (i.e., the metalorganic flowing into the chamber can have a Reynolds number greater than 2,000) or with a substantially laminar flow.

In some embodiments, the means for positioning a substrate is suitable for positioning a substrate about 1 cm to about 4 cm, about 1 cm to about 3.5 cm, about 1 cm to about 3 cm, about 1 cm to about 2.5 cm, about 1 cm to about 2 cm, about 1 cm to about 1.5 cm, about 1.5 cm to about 4 cm, about 1.5 cm to about 3.5 cm, about 1.5 cm to about 3 cm, about 1.5 cm to about 2.5 cm, about 2 cm to about 4 cm, about 2 cm to about 3.5 cm, about 2 cm to about 3 cm, about 3 cm to about 4 cm, about 1 cm, about 1.5 cm, about 2 cm, about 2.5 cm, about 3 cm, about 3.5 cm, or about 4 cm from a metalorganic precursor source.

In some embodiments, a means for sputtering the target material from the surface is a power supply suitable for generating a plasma having a power density of about 3 W/cm² to about 25 W/cm². For laboratory-scale coating, a power supply capable of providing about 1 kW to about 10 kW can be used for plasma generation. For industrial-scale production, higher powers can be used (e.g., about 12 kW or more, about 15 kW or more, about 20 kW or more, about 25 kW or more, about 30 kW or more, about 40 kW or more, about 50 kW or more, about 75 kW or more, or about 100 kW or more), depending on the dimensions of the surface to be coated.

In some embodiments, the apparatus further comprises a means for controlling a temperature of a substrate at about 25° C. to about 500° C. Means for controlling a temperature of a substrate include, but are not limited to, a resistive heating element, a block heater, a cathode heater, a dielectric heater, a convective heater, an induction heater, an infrared heater, a quartz-halogen heater, and combinations thereof. The heating can be radiative, conductive (via contact), or a combination thereof.

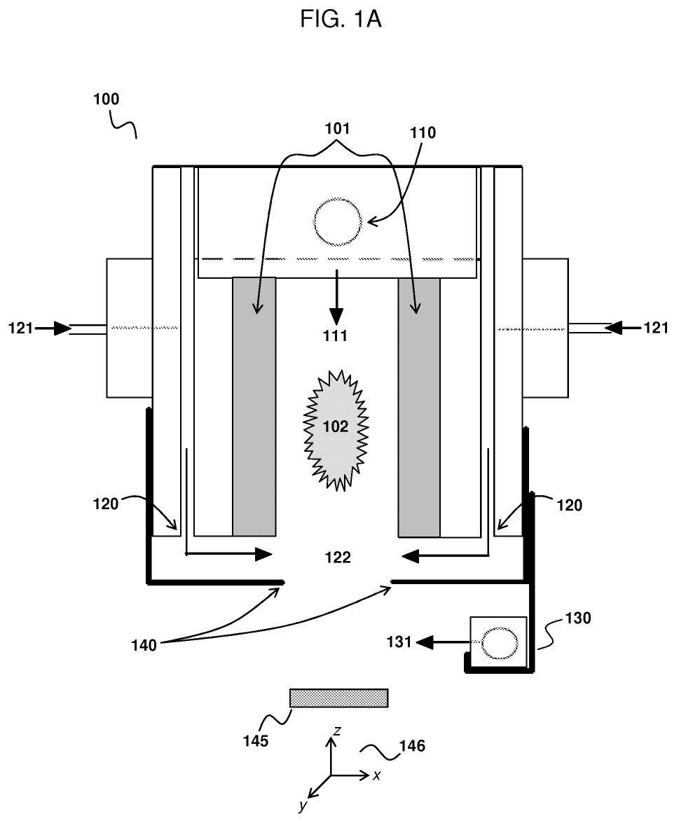

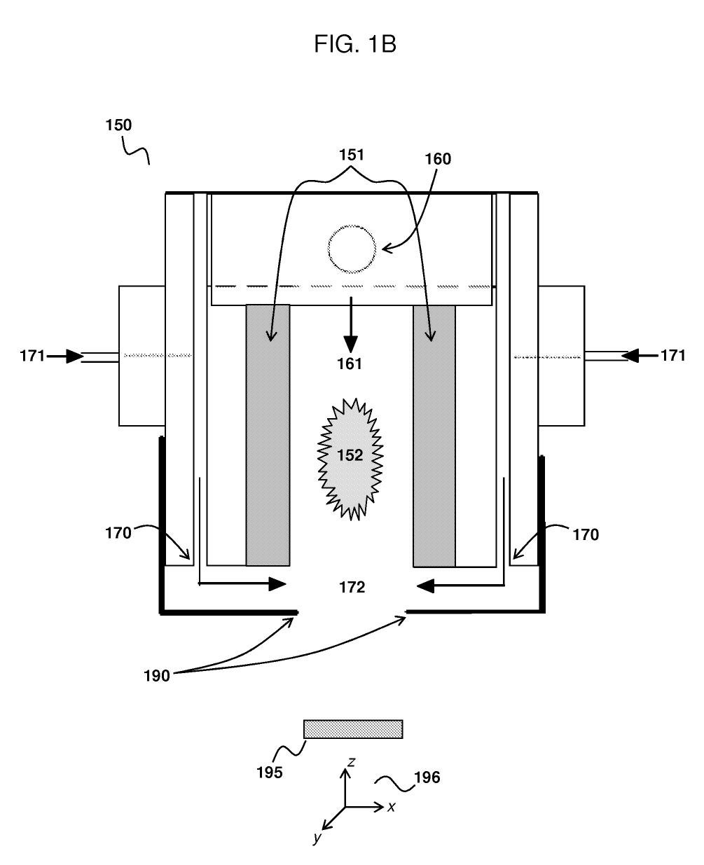

FIG. 1A provides a cross-sectional representation of an apparatus of the present invention in the x-z plane that includes a generally rectangular, linear hollow cathode whose long axis is in the y-direction. Referring to FIG. 1, the apparatus, 100, comprises a surface that includes a target material, 101, a gas source, 110, and a metalorganic precursor source, 130. The target material is removed from the surface, 101, by hollow cathode sputtering in which the gas source, 110, introduces a gas suitable for creating a plasma, 102, proximate to the surface, 101. The plasma sputters the target material from the surface, and the sputtered material is deposited on the substrate, 145.

When argon is used as a gas for plasma generation, an argon flow rate of about 5 standard liters per minute (slm) to about 15 slm, about 5 slm to about 10 slm, about 5 slm to about 7.5 slm, about 7.5 slm to about 15 slm, about 7.5 slm to about 10 slm, about 10 slm to about 15 slm, about 5 slm, about 7.5 slm, about 10 slm, about 12.5 slm, or about 15 slm can be provided.

Referring to FIG. 1A, the apparatus, 100, includes a gas source, 120, suitable for introducing a reactive gas (e.g., an oxidant), 121, into a region of the apparatus, 122, that is between the surface, 101, and the substrate, 145. Flanges, 140, provide a channel for channeling a reactive gas into a region of the apparatus proximate to plasma generation, 102.

When oxygen (O₂) is used as a reactive gas, an oxygen flow rate of about 10 standard cubic centimeters per minute (sccm) to about 300 sccm, about 10 sccm to about 250 sccm, about 10 sccm to about 200 sccm, about 10 sccm to about 150 sccm, about 10 sccm to about 100 sccm, about 10 sccm to about 75 sccm, about 10 sccm to about 50 sccm, about 10 sccm to about 25 sccm, about 25 sccm to about 300 sccm, about 25 sccm to about 250 sccm, about 25 sccm to about 200 sccm, about 25 sccm to about 150 sccm, about 25 sccm to about 100 sccm, about 25 sccm to about 75 sccm, about 25 sccm to about 50 sccm, about 50 sccm to about 300 sccm, about 50 sccm to about 250 sccm, about 50 sccm to about 200 sccm, about 50 sccm to about 150 sccm, about 50 sccm to about 100 sccm, about 100 sccm to about 300 sccm, about 100 sccm to about 250 sccm, about 100 sccm to about 200 sccm, about 150 sccm to about 300 sccm, about 150 sccm to about 250 sccm, about 150 sccm to about 200 sccm, about 200 sccm to about 300 sccm, about 10 sccm, about 15 sccm, about 20 sccm, about 25 sccm, about 50 sccm, about 75 sccm, about 100 sccm, about 125 sccm, about 150 sccm, about 175 sccm, about 200 sccm, about 225 sccm, about 250 sccm, or about 300 sccm can be provided.

Referring to FIG. 1A, the apparatus, 100, includes a means for positioning the substrate, 145, a distance from the surface, 101. Thus, the apparatus can include a means for varying the distance (in the z-direction) between the surface, 101, and the substrate, 145. A substrate-positioning means can also provide for control of the substrate position in the x-, y-, and/or z-directions, 146. Thus, the substrate, 145, can be moved relative to the sputtering surface, 101, before and/or during, as well as after depositing a doped and/or alloyed semiconductor layer. A means for positioning a substrate a distance from the surface can include a platen, a conveyor, an elevator, a robot arm, a shelf, a belt, rollers, and the like, and combinations thereof.

Referring to FIG. 1A, the apparatus, 100, includes a metalorganic source, 130. In FIG. 1A, the metalorganic source is positioned such that a metalorganic is introduced into the apparatus at a point, 131, between the surface, 101, and the substrate, 145. In this configuration, the metalorganic is capable of interacting with at least a portion of the afterglow region of a plasma, 102. It is also within the scope of the present invention for a metalorganic source to introduce a metalorganic directly into a region proximate the surface, 101, e.g, via gas source, 110. Alternatively, a metal organic source can be located proximate to the reactive gas source, 120.

FIG. 1B provides a cross-sectional representation of an apparatus of the present invention. Referring to FIG. 1B, the apparatus, 150, comprises a surface that includes a target material, 151, and a gas source, 160, suitable for providing a gas and a metalorganic precursor to the apparatus. The target material is removed from the surface, 151, by hollow cathode sputtering in which the gas source, 160, introduces a gas suitable for creating a plasma, 152, proximate to the surface, 151. The plasma sputters the target material from the surface, and the sputtered material is deposited on the substrate, 195. A second gas source, 170, is also provided and is suitable for introducing a reactive gas, 171, into the chamber that can react with the sputtered target material and/or a dopant deposited from a metalorganic precursor. The reacting can occur in an afterglow region of the plasma, 172, and/or on the substrate, 195. The apparatus also includes a means for controlling the three-dimensional position, 196, of the substrate, 195.

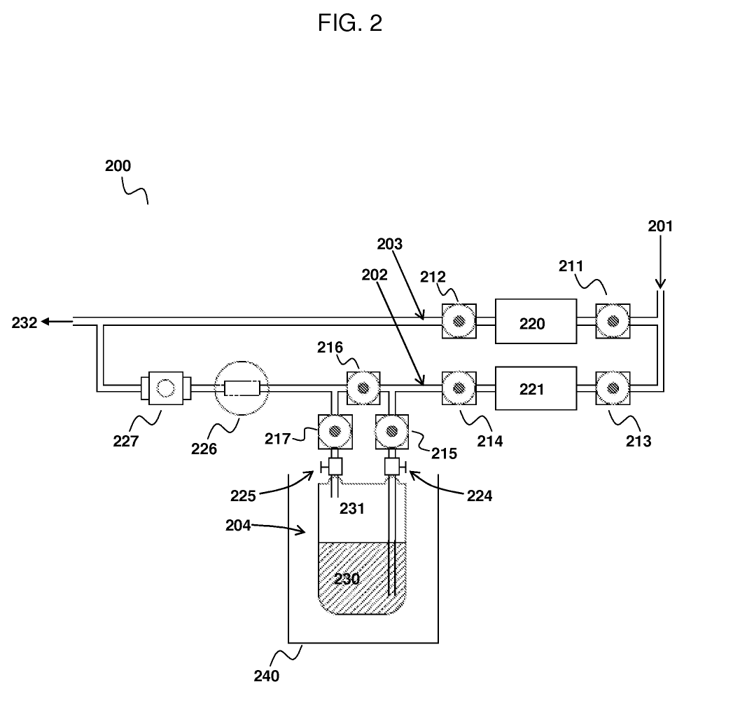

The metalorganic precursor source can be a solid, liquid or a gas under ambient conditions. In some embodiments, the metalorganic is a liquid at or near ambient conditions or a solid capable of dissolution in a solvent at or near ambient conditions. FIG. 2 provides a schematic representation of a cross-sectional view of a portion of an apparatus suitable for providing a metalorganic precursor to a deposition chamber. Referring to FIG. 2, the apparatus, 200, includes a gas supply, 201, suitable for providing a carrier gas supply, 202, and a push gas supply, 203. Gases suitable for use as carrier and/or push gases for a metalorganic include inert gases such as He, Ne, Kr, Ar, Xe, and combinations thereof. While FIG. 2 depicts a single gas source, 201, that is branched to form the push gas, 220, and carrier gas, 221, lines, it is also within the scope of the present invention to include separate gas sources for the push and carrier gas lines.

The metalorganic precursor apparatus, 200, includes pneumatic switches, 211, 212, 213, 214, 215, 216 and 217, which can be individually actuated. Mass flow controllers, 220 and 221, are used to control the flow of push and carrier gases, respectively.

A push gas ensures proper mixing of a metalorganic with other species in the deposition chamber, providing uniform incorporation of a dopant into a doped semiconductor layer. In some embodiments, a push gas is utilized at a flow rate of 0 slm to about 5 slm, about 0.5 slm to about 5 slm, about 0.5 slm to about 4 slm, about 0.5 slm to about 3 slm, about 0.5 slm to about 2.5 slm, about 0.5 slm to about 2 slm, about 0.5 slm to about 1 slm, about 1 slm to about 5 slm, about 1 slm to about 4 slm, about 1 slm to about 2 slm, about 2 slm to about 5 slm, about 2 slm to about 4 slm, about 2.5 slm to about 5 slm, 0 slm, about 0.5 slm, about 1 slm, about 1.5 slm, about 2 slm, about 2.5 slm, about 3 slm, about 4 slm, or about 5 slm. These ranges are suitable for a cathode assembly having a length of about 50 cm, and should be scaled appropriately for larger and smaller cathode assemblies.

In some embodiments, a carrier gas is utilized at a flow rate of 0 sccm to about 200 sccm, about 10 sccm to about 200 sccm, about 10 sccm to about 150 sccm, about 10 sccm to about 100 sccm, about 10 sccm to about 50 sccm, about 25 sccm to about 200 sccm, about 25 sccm to about 150 sccm, about 25 sccm to about 100 sccm, 25 sccm to about 50 sccm, about 50 sccm to about 200 sccm, about 50 sccm to about 150 sccm, about 50 sccm to about 100 sccm, or about 100 sccm to about 200 sccm. These ranges are suitable for a cathode assembly having a length of about 50 cm, and should be scaled appropriately for larger and smaller cathode assemblies.

Referring to FIG. 2, prior to operation, manual valves, 224 and 225, are opened. Carrier gas, 202, is then flowed into bubbler, 204, which contains a metalorganic, 230. The bubbler, 204, includes a temperature control device, 240, capable of either heating or cooling the metalorganic. In some embodiments, the temperature of the bubbler, 204, is controlled to at about −10° C. to about 50° C., about 0° C. to about 50° C., about 10° C. to about 50° C., about 25° C. to about 50° C., about −10° C., about 0° C., about 10° C., about 25° C., or about 50° C.

The internal pressure of the bubbler can also be controlled. In some embodiments, an internal pressure of the bubbler is about 100 Torr to about 900 Torr, about 100 Torr to about 800 Torr, about 100 Torr to about 760 Torr, about 100 Torr to about 500 Torr, about 100 Torr to about 250 Torr, about 200 Torr to about 900 Torr, about 200 Torr to about 760 Torr, about 200 Torr to about 500 Torr, about 400 Torr to about 900 Torr, about 400 Torr to about 760 Torr, about 500 Torr to about 900 Torr, about 500 Torr to about 760 Torr, about 760 Torr to about 900 Torr, about 100 Torr, about 200 Torr, about 400 Torr, about 500 Torr, about 600 Torr, about 750 Torr, about 760 Torr, about 800 Torr, or about 900 Torr.

Referring to FIG. 2, volatized metalorganic, 231, is carried from the bubbler to the deposition chamber, 232, after passing through a pressure transducer, 226, and a control valve, 227. Thus, the flow rate of the metalorganic provided to the chamber, 232, can be varied continuously.

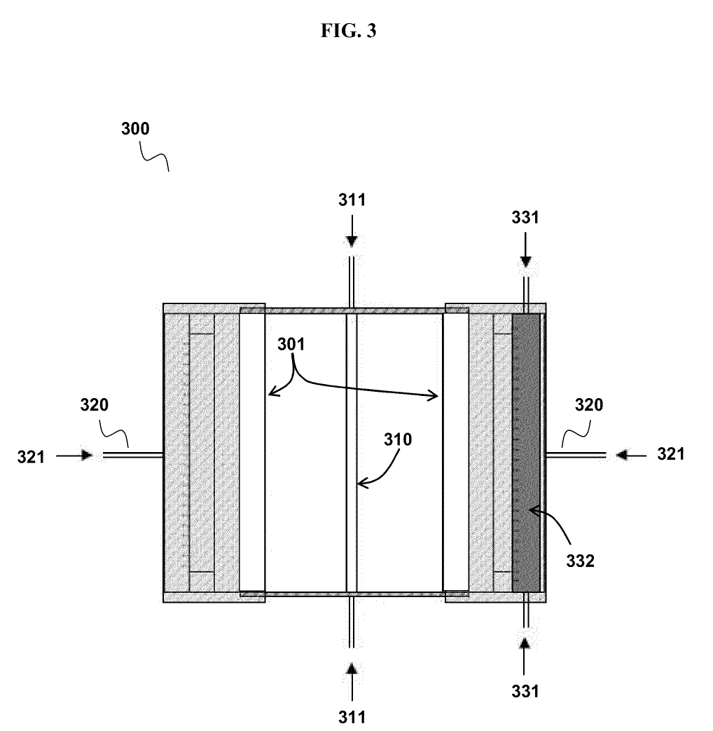

FIG. 3 provides a schematic representation of a bottom (top) view of a portion of a deposition apparatus of the present invention intended for downwards (upwards) deposition. Referring to FIG. 3, depicted is an apparatus, 300, comprising a surface that includes a target material, 301, and a gas source, 310. In some embodiments, the gas source, 310, provides a gas suitable for striking a plasma proximate to the surface, 301. The gas source can distribute the gas uniformly into a space between adjacent surfaces that contain one or more target materials. Also depicted are inlet ports, 320, suitable for providing a reactive gas, 322, to the deposition chamber. Also depicted is a linear manifold, 332, which serves as a source of a metalorganic, 331. The manifold ensures that the metalorganic is distributed evenly into the apparatus, to provide uniform doping and/or alloying a semiconductor layer.

Having generally described the invention, a further understanding can be obtained by reference to the examples provided herein. These examples are given for purposes of illustration only and are not intended to be limiting.

### EXAMPLES

### Example 1

Zinc oxide (ZnO) and gallium-doped zinc oxide (GZO) films were deposited on glass substrates by a method of the present invention using an apparatus depicted in FIGS. 1-3. A zinc sputtering target was utilized for all depositions. An argon plasma was generated in the hollow cathode portion of the apparatus (the length of the cathode was about 15 cm), and an oxidant (O₂) was introduced into the deposition chamber. Sputtered zinc was carried to the substrate and mixed with the oxidant by the argon flow. For the GZO films the metalorganic was triethylgallium (TEGa), which was introduced in the deposition chamber using argon as a carrier gas. The metalorganic TEGa was dissociated by the argon plasma and carried onto the substrate where it was co-deposited with the zinc oxide. The deposition conditions are outlined in the Tables below.

TABLES
Deposition conditions and flow rates for undoped ZnO and GZO layers
(deposited using a hollow cathode assembly
having a length of about 15 cm) . . .

| Sam- | Chamber | Deposition | Power | | Flow conditions | |
|---|---|---|---|---|---|---|
| ple | pressure | Temperature | Frequency | Power | Ar | O₂ |
| 598 | 180 mTorr | 200° C. | 200 kHz | 400 W | 2 SLM | 11 sccm |
| 599 | 180 mTorr | 200° C. | 200 kHz | 400 W | 2 SLM | 11 sccm |
| 597 | 180 mTorr | 200° C. | 200 kHz | 400 W | 2 SLM | 11 sccm |
| 594b | 180 mTorr | 200° C. | 200 kHz | 400 W | 2 SLM | 39 sccm |

| | Bubbler | Bubbler | | |
|---|---|---|---|---|
| Sample | Temperature | Pressure | Ar Push | Ar Carrier |
| 598 | n/a | n/a | 0 | 0 |
| 599 | 10° C. | 650 Torr | 100 sccm | 50 sccm |
| 597 | 10° C. | 550 Torr | 100 sccm | 50 sccm |
| 594b | 10° C. | 400 Torr | 200 sccm | 100 sccm |

This example illustrates the ability to deposit doped semiconductor layers having a variable dopant concentration without the need for multiple sputtering targets. Thus, the present invention provides a significant improvement over known physical vapor deposition methods (such as sputtering) used to prepare doped and/or alloyed semiconductor materials.

### Example 2

The composition of the ZnO film and GZO films prepared in Example 1 was characterized using inductively coupled plasma optical emission spectrometry (ICP-OES). The results are presented in the Table below.

TABLE
ICP measurements of ZnO and GZO films.

| | Ga | Ga | | | |
|---|---|---|---|---|---|
| | (403.298) | (417.206) | Zn (202.551) | Zn (206.200) | |
| Sample | ppm | ppm | ppm | ppm | % Ga |
| Standard | 10.00 | 10.00 | 10.00 | 10.00 | — |
| Blank | 0.00 | 0.00 | 0.00 | 0.00 | — |
| 598 | −0.05 | 0.063 | 187.31 | 190.92 | 0% |
| 599 | 21.54 | 23.73 | 583.07 | 675.55 | 3.27% |
| 597 | 6.17 | 6.09 | 159.88 | 157.02 | 3.63% |
| 594b | 30.78 | 29.17 | 327.17 | 390.98 | 7.84% |

Referring to the above Table, gallium concentrations of about 3.3% to about 7.8% were obtained. The gallium concentration of the GZO films can be correlated with the flow rate of argon and TEGa into the deposition chamber, as well as the TEGa bubbler temperature and pressure.

### Example 3

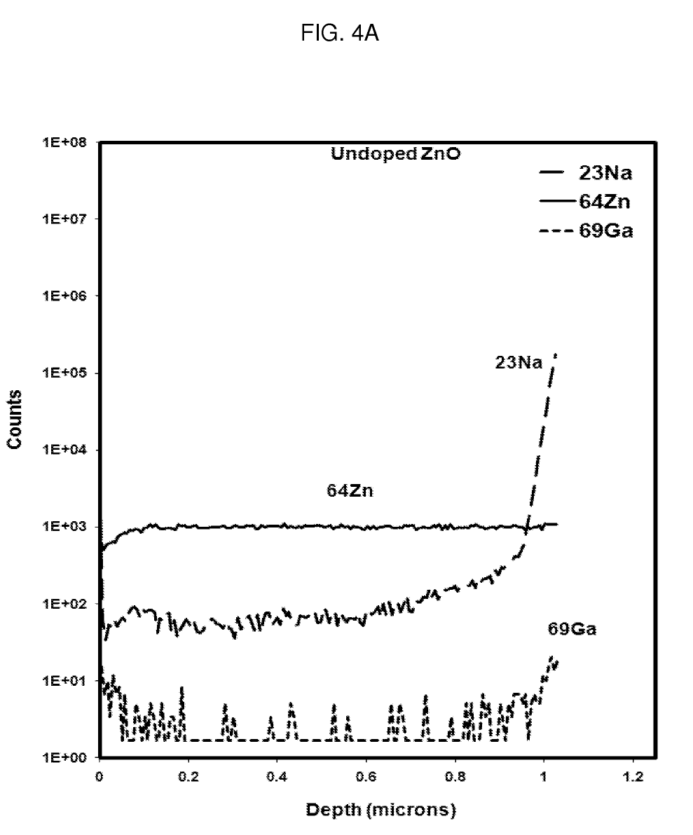

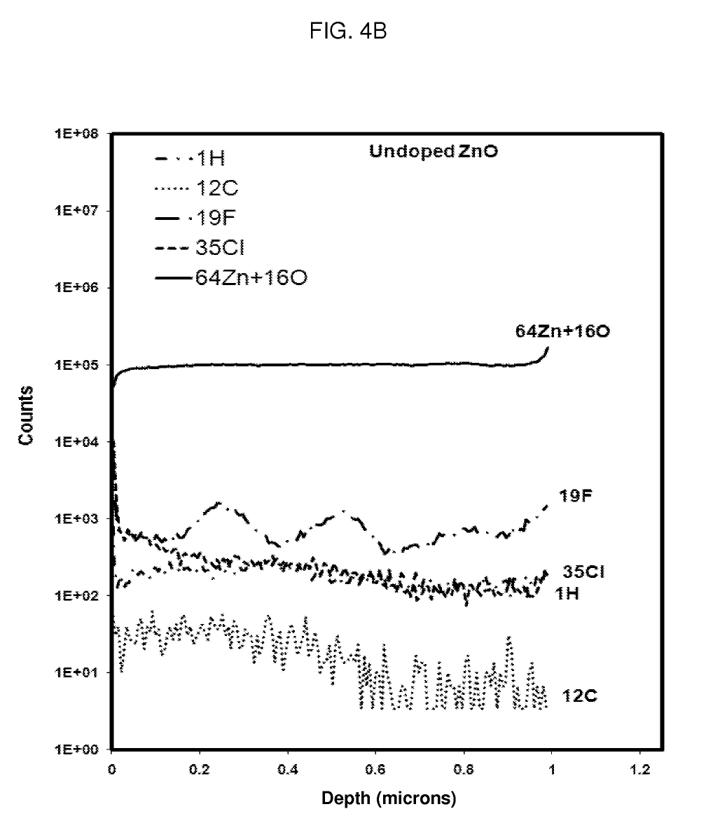

The compositional uniformity of the ZnO film and GZO films prepared in Example 1 was characterized using dynamic Secondary Ion Mass Spectrometry (d-SIMS). The depth profiles obtained from the d-SIMS analysis are presented graphically in FIGS. 4A-4B, 5A-5B and 6A-6B.

The depth profile for the undoped ZnO layer is provided in FIGS. 4A-4B. Referring to FIG. 4A, the depth profile for zinc, sodium and gallium in the ZnO layer indicates that the ZnO layer is free from gallium (i.e., gallium is below the detection limit), and substantially uniform with respect to the concentration of zinc. The sodium signature arises from the underlying glass substrate.

Referring to FIG. 4B, the depth profile for zinc+oxygen, fluorine, chlorine, hydrogen and carbon in the ZnO layer indicates that the ZnO film is substantially uniform with respect to zinc+oxygen, and substantially free of carbon. The ZnO film contains very low levels of the halides (i.e., F and Cl) and hydrogen.

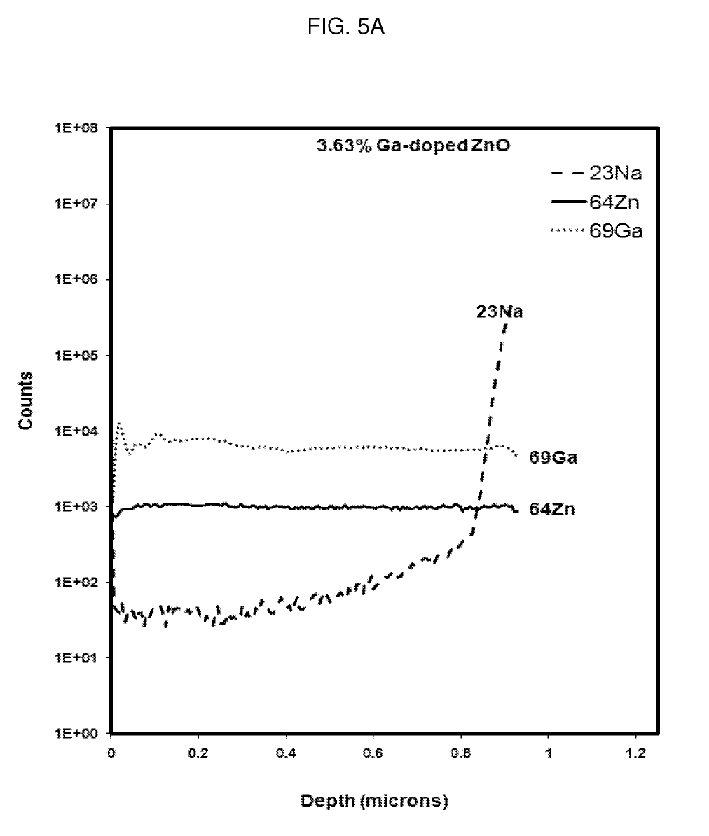

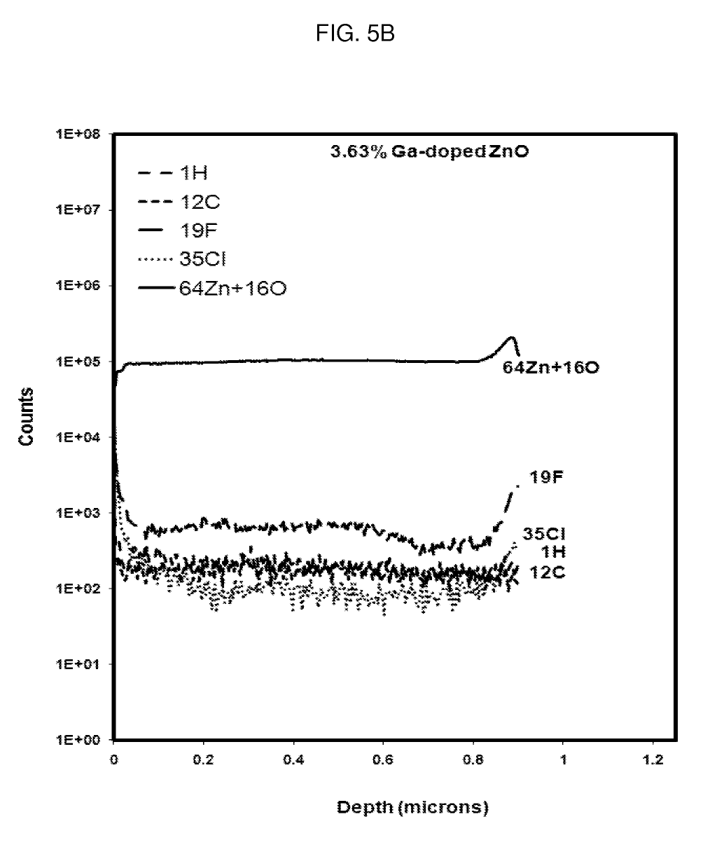

The depth profile for a GZO layer containing about 3.6% gallium is provided in FIGS. 5A-5B. Referring to FIG. 5A, the depth profile for zinc, sodium and gallium in the GZO layer indicates that the GZO layer contains a substantially uniform concentration of gallium. The sodium signature arises from the underlying glass substrate.

Referring to FIG. 5B, the depth profile for zinc+oxygen, fluorine, chlorine, hydrogen and carbon in the GZO layer indicates that the GZO layer is substantially uniform with respect to zinc+oxygen, and contains similar amounts of the halides and hydrogen as the ZnO layer (see FIG. 4B). The carbon content of the GZO layer is approximately one order of magnitude higher than the undoped ZnO layer, suggesting the presence of trace amounts of carbon in the GZO layer. This is not unexpected due to the used of the metalorganic as the gallium source.

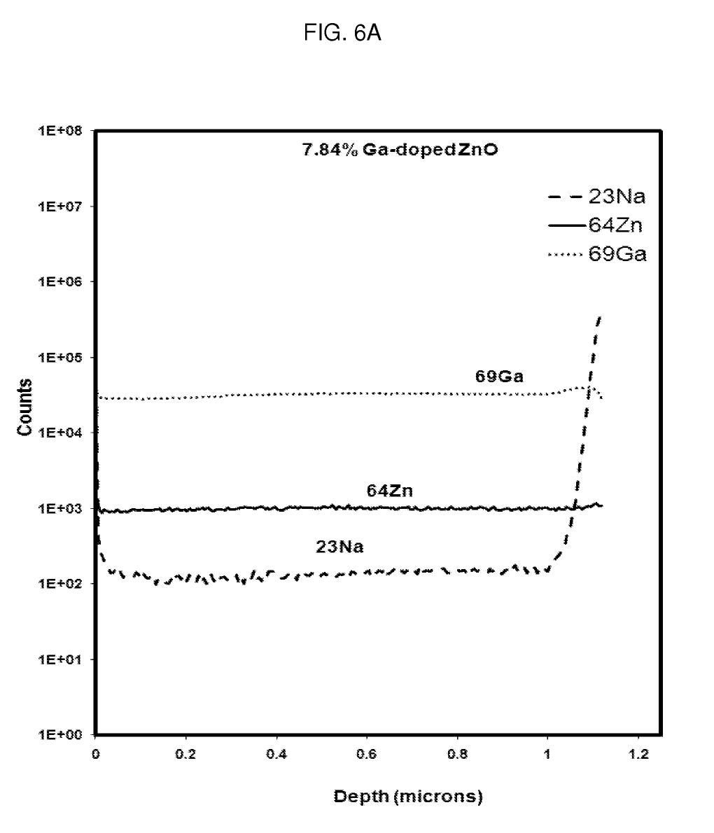

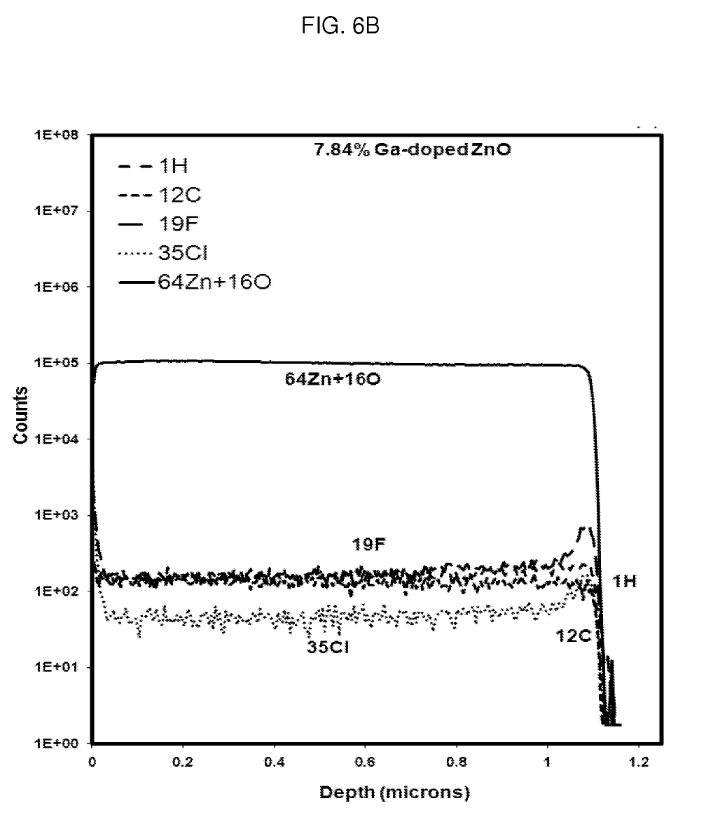

The depth profile for a GZO layer containing about 7.8% gallium is provided in FIGS. 6A-6B. Referring to FIG. 6A, the depth profile for zinc, sodium and gallium in the GZO layer contains a substantially uniform concentration of gallium. The sodium signature arises from the underlying glass substrate.

Referring to FIG. 6B, the depth profile for zinc+oxygen, fluorine, chlorine, hydrogen and carbon in the GZO layer indicates that the GZO layer is substantially uniform with respect to zinc+oxygen, and contains similar amounts of the halides and hydrogen as the ZnO layer (see FIG. 4B). The carbon content of the GZO layer is similar to that observed in the 3.6%-Ga GZO layer (see FIG. 5B).

### Example 4

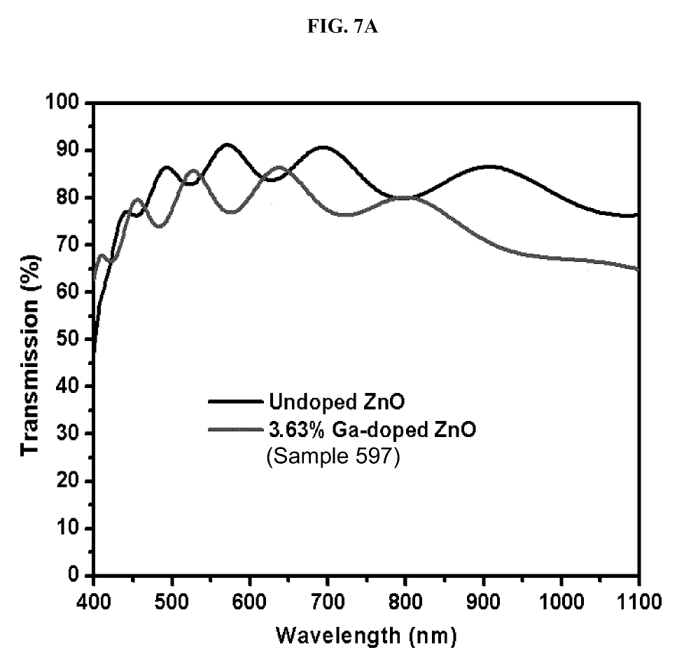

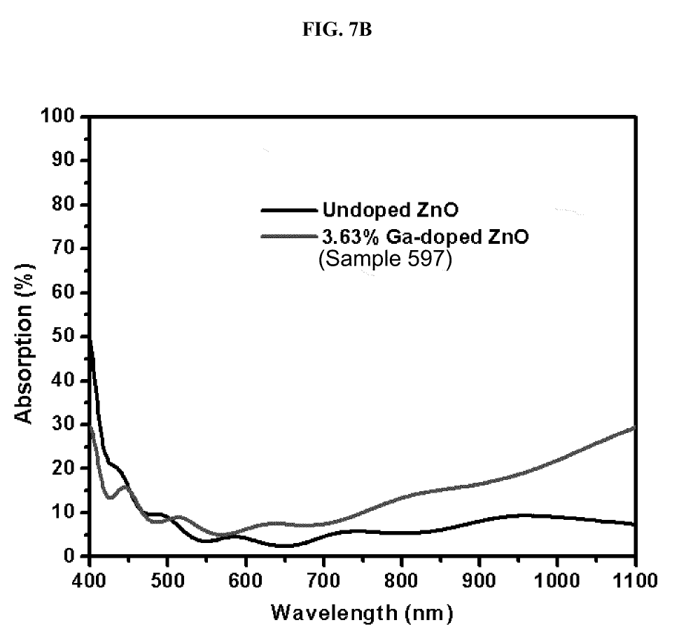

The optical properties of the ZnO and GZO layers prepared in Example 1 were characterized by optical transmission and reflection spectroscopy. The results are presented graphically in FIGS. 7A-7B.

Referring to FIG. 7A, the optical transmission properties in the visible and near-infrared (near-IR) regions of the spectrum are provided for the ZnO layer, as well as the GZO layer containing about 3.6% gallium. The difference in the secondary structure of the transmission spectra for the layers arises from differences in the layer thickness (ZnO=930 nm, whereas GZO=850 nm). The GZO layer provided similar optical transmission in the visible region of the spectrum, whereas the near-IR transmission of the GZO layer was about 10% less than that of the undoped ZnO layer.

Referring to FIG. 7B, the optical absorption properties in the visible and near-IR regions of the spectrum are provided for the ZnO layer, as well as the GZO layer containing about 3.6% gallium. The GZO layer provided similar optical absorption in the visible region of the spectrum, whereas the absorption of the GZO layer in the near-IR was about 20% greater than that of the undoped ZnO layer, which increased with increasing wavelength.

### Example 5

The electrical properties (sheet resistance and Hall mobility) of the ZnO layer and GZO layers prepared in Example 1 were characterized. The results are provided in the Table below.

TABLE
Room temperature electrical properties of ZnO and GZO
layers on glass substrates.

| | Film | Ga | Sheet | Carrier | Hall |
|---|---|---|---|---|---|
| Sample | Thickness | Conc. | Resistance | Conc. | Mobility |
| 598 | 930 nm | 0% | 140 Ω/sq | 3.47E19 cm⁻³ | 13.9 cm²/ |
| | | | | | V · s |
| 597 | 850 nm | 3.63% | 12 Ω/sq | 2.67E20 cm⁻³ | 23 cm²/ |
| | | | | | V · s |
| 594b | 800 nm | 7.84% | 13 Ω/sq | 5.74E20 cm⁻³ | 10.5 cm²/ |
| | | | | | V · s |

Referring to the above Table, the GZO layers provided sheet resistance values more than one order of magnitude less than the undoped ZnO layer. Furthermore, the Hall mobility for the GZO layer that contained about 3.6% gallium was nearly double that of the undoped ZnO layer. The more heavily doped GZO layer (containing 7.8% Ga) suffered a drop in mobility, as is commonly observed. However, the sheet resistance of 12 Ω/sq was suitably low for the GZO layer to be used as a TCO for solar cells.

### Example 6

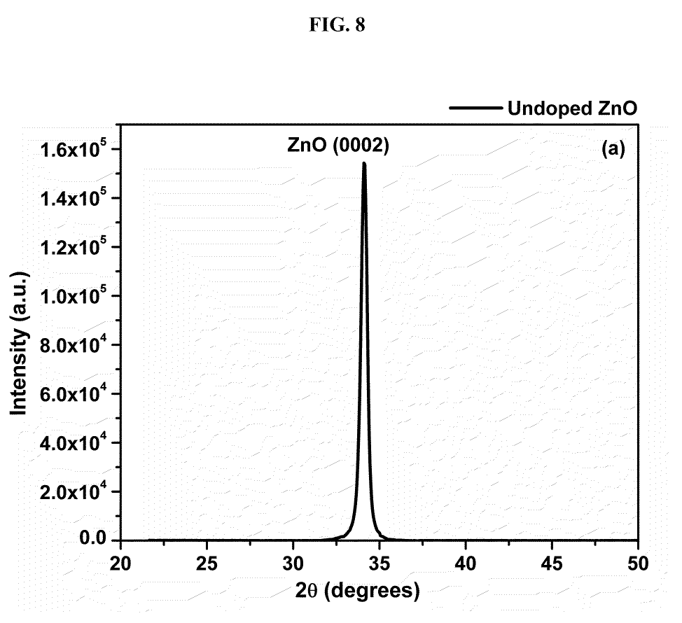

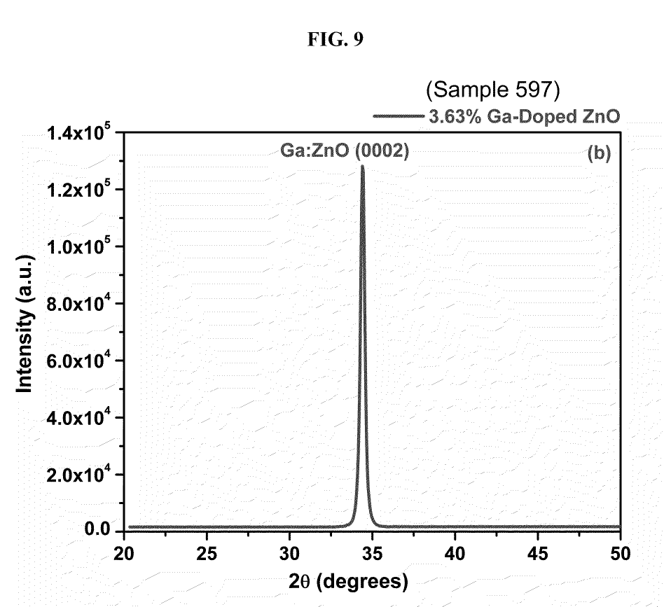

The structure of the ZnO layer and a GZO layer prepared in Example 1 was characterized by x-ray diffraction. The results are provided graphically in FIGS. 8 and 9.

Referring to FIG. 8, the undoped ZnO layer provides a single peak in the x-ray diffraction spectrum at approximately 2θ=34°, which is indicative of a ZnO (0002) lattice having a predominantly c-axis orientation.

Referring to FIG. 9, the GZO layer containing about 3.6% gallium also provided an x-ray diffraction spectrum containing a single peak at approximately 2θ=34°, which is indicative of a ZnO (0002) lattice having a predominantly c-axis orientation. No additional peaks were observed for GZO layer, indicating the absence of gallium segregation, or the formation of additional ZnO phases.

### Example 7

A co-doped aluminum-gallium-doped ZnO layer was deposited on a glass substrate by a method of the present invention. A zinc sputtering target was utilized for all depositions. The length of the cathode was 50 cm. An argon plasma was generated in the hollow cathode portion of the apparatus, and an oxidant (O₂) was introduced into the deposition chamber. Sputtered zinc was carried to the substrate and mixed with the oxidant by the argon flow. Aluminum was also sputtered from the hollow cathode and co-deposited with the zinc. The metalorganic was TEGa, which was introduced in the deposition chamber using argon as a carrier gas. The deposition conditions are outlined in the Tables below.

TABLES
Deposition conditions and flow rates for undoped ZnO and GZO layers.

| Sam- | Chamber | Deposition | Power | | Flow conditions | |
|---|---|---|---|---|---|---|
| ple | pressure | Temperature | Frequency | Power | Ar | O₂ |
| 583 | 271 | 337° C. | 200 kHz | 2000 W | 10 SLM | 19 sccm |
| | mTorr | (Initial) | | | | |
| | | 235° C. | | | | |
| | | (Final) | | | | |

| | Bubbler | Bubbler | | Ar | |
|---|---|---|---|---|---|
| Sample | Temperature | Pressure | Ar Push | Carrier | Time |
| 583 | 10° C. | 500 Torr | 200 sccm | 10 slm | 15 min. |

The film thickness was about 1100 nm, and the sheet resistance was 2-3 Ω/sq (as determined by the method described in Example 5). The AGZO layer contained gallium in a molar concentration of 1.1% and aluminum in a molar concentration of 3.4% (as determined by ICP-OES).

This example illustrates the ability to deposit co-doped semiconductor layers having a controlled dopant concentration. By this method, the concentration of gallium in the co-doped AGZO layer can be easily controlled and varied as desired.

### CONCLUSION

These examples illustrate possible embodiments of the present invention. While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

All documents cited herein, including journal articles or abstracts, published or corresponding U.S. or foreign patent applications, issued or foreign patents, or any other documents, are each entirely incorporated by reference herein, including all data, tables, figures, and text presented in the cited documents.

What is claimed is:

1. A method for depositing a semiconductor layer on a substrate, the method comprising:
sputtering a material from a target onto a substrate to provide a semiconductor layer, while simultaneously doping and/or alloying the semiconductor layer with a metalorganic precursor.

2. The method of claim 1, wherein the sputtering the material and the doping and/or alloying occur within a single deposition chamber.

3. The method of claim 1, wherein the doping and/or alloying comprises providing to the substrate a decomposition product of the metalorganic precursor.

4. The method of claim 3, wherein the decomposition of the metalorganic precursor occurs via plasma activation, thermal activation, or a combination thereof.

5. The method of claim 1, wherein the sputtering comprises a target that includes a metal selected from: zinc, aluminum, titanium, tin, indium, hafnium, an oxide thereof, and combinations thereof.

6. The method of claim 1, wherein the sputtering includes a process selected from:
magnetron sputtering and non-magnetron sputtering.

7. The method of claim 6, wherein the sputtering comprises an excitation provided by radiofrequency current, mid-frequency current, direct current, or pulsed direct current.

8. The method of claim 1, further comprising providing a reactive gas during the sputtering and the doping and/or alloying.

9. The method of claim 1, wherein the sputtering a material from a target comprises:
(a) providing a surface, wherein one or more portions of the surface include a target material;
(b) flowing a gas into a region proximate to the surface;
(c) generating a plasma in the region proximate to the surface;
(d) sputtering the target material from the surface; and
(e) depositing the sputtered target material on the substrate.

10. The method of claim 9, wherein the flowing a gas comprises an inert gas.

11. The method of claim 9, further comprising: reacting at least a portion of the sputtered target material with a reactive species.

12. The method of claim 11, wherein the reacting comprises providing a reactive oxidizing species to the substrate.

13. The method of claim 1, wherein the doping and/or alloying comprises:
(a) flowing a metalorganic precursor into the deposition chamber;
(b) decomposing the metalorganic precursor to form a doping and/or alloying species; and
(c) providing the doping and/or alloying species to the substrate.

14. The method of claim 13, wherein the flowing comprises providing the metalorganic precursor in an after-glow region of a plasma.

15. The method of claim 13, wherein the flowing includes a metalorganic precursor that contains a metal selected from: a group IIA element, a transition metal, a group III element, a group VI element, and combinations thereof.

16. The method of claim 13, wherein the flowing includes a metalorganic precursor containing a metal selected from: gallium, aluminum, indium, magnesium, cadmium, iron, and combinations thereof.

17. The method of claim 13, wherein the flowing includes a metalorganic precursor selected from: trimethylgallium, triethylgallium, tripropylgallium, triethylaluminum, tripropylaluminum, tributylaluminum, diethylaluminum hydride, dipropylaluminum hydride, dibutylaluminum hydride, trimethylindium, bismethylcyclopentadienyl magnesium, dimethylcadmium, bicyclopentadienyl iron, and combinations thereof.

18. The method of claim 13, wherein the flowing includes a metalorganic precursor containing gallium, and the sputtering comprises one or more targets that include zinc, aluminum, or a combination thereof.

19. The method of claim 1, wherein the sputtering the material and the doping and/or alloying provides a dynamic deposition rate for the semiconductor layer of about 5 nm·m/min to about 100 nm·m/min.

20. A product prepared by the process of claim 1.

21. The product of claim 20, wherein the product is a gallium-doped zinc oxide layer having a refractive index of less than about 1.80, as measured at a wavelength of about 600 nm.

22. The product of claim 20, wherein the product is a doped zinc oxide layer comprising aluminum, gallium, or a combination thereof in a molar concentration of about 0.1% to about 30%.

23. The product of claim 22, wherein the doped zinc oxide layer has a specific crystal orientation and comprises gallium in a molar concentration of about 0.1% to about 15%.

24. The product of claim 22, wherein the doped zinc oxide layer has a specific crystal orientation and comprises aluminum in a molar concentration of about 0.1% to about 15%.

25. The product of claim 20, wherein the product is a zinc oxide layer alloyed with magnesium, cadmium, or a combination thereof.

26. The product of claim 20, wherein the product is a doped and/or alloyed zinc oxide layer having a single crystalline orientation.

27. An apparatus comprising a deposition chamber that includes:
(a) a surface that includes a target material;
(b) a cathode assembly for supporting the surface that includes a target material;
(c) a means for sputtering the target material from the surface;
(d) a gas source;
(e) a metalorganic precursor source; and
(f) a means for positioning a substrate a distance from the surface.

28. The apparatus of claim 27, wherein the cathode assembly includes a linear hollow cathode.

29. The apparatus of claim 27, wherein the gas source comprises an inert gas source and a reactive gas source.

30. The apparatus of claim 27, wherein the means for positioning a substrate is suitable for positioning a substrate about 3 cm to about 8 cm from the surface that includes a target material or from an exit aperture of a hollow cathode.

31. The apparatus of claim 27, wherein the means for positioning a substrate is suitable for positioning a substrate about 1 cm to about 4 cm from metalorganic precursor source.

32. The apparatus of claim 27, further comprising an oxidant source.
